(19) United States
(12) Patent Application Publication
(10) Pub. No.: US 2008/0316628 A1
(43) Pub. Date: Dec. 25, 2008

(54) Density filter, method of forming the density filter and apparatus thereof

(75) Inventors: Katsura Nakajima, Nirasaki-shi (JP); Shoichi Kohya, Minami Arupusu-shi (JP)

Correspondence Address: KANESAKA BERNER AND PARTNERS LLP, 1700 DIAGONAL RD, SUITE 310, ALEXANDRIA, VA, 22314-2848, US

(73) Assignee: NISCA CORPORATION, Minamikoma-gun (JP)

(21) Appl. No.: 12/213,626

(22) Filed: Jun. 23, 2008

(30) Foreign Application Priority Data
Jun. 25, 2007 (JP) 2007-166249
Jun. 25, 2007 (JP) 2007-166250
Jun. 29, 2007 (JP) 2007-171780

(51) Int. Cl. G02B 5/22; B32B 37/06; C23C 14/34

(52) U.S. Cl. 359/888; 156/272.6; 204/298.28

(57) ABSTRACT

A film coating method enables, when forming film layers in response to optical characteristics on a substrate, to coat gradation range layers of decreasing thickness without distributions, and to coat films on a plurality of substrates at the same time. The gradation range layer is formed by sputtering evaporation targets of dielectric substances with an introduction gas, followed by forming the films with compounds generated by applying a reactive gas to the films.

### BACKGROUND OF THE INVENTION AND RELATED ART STATEMENT

The present invention relate to a density filter for adjusting quantity of light of an imaging camera, a method for forming the density filter and an apparatus for forming the same. In particular, the invention relates to a gradation film coating method and a film coating apparatus or equipment where a density characteristic of the density filter continuously decreases.

In general, the density filter has broadly been used in IRIS. The density filter is form by a thin film, that has a superior light absorption characteristic, on a resin substrate. The density filter is known in coating thin films having uniform mono-density, in dividing film coatings into several ranges of different densities, and in coating thin films with gradation of density distribution which continuously changes.

Recently, with the advancement of high resolution imaging cameras, if closing quantity of light under a condition of bright subjects to be imaged, deteriorations in picture quality owing to image defocusing occur. Therefore, as disclosed in, for example, Patent Document 1 (Japanese Patent No. 2754518), the density filter is attached to a blade for adjusting quantity of light in order to suppress diffraction phenomena, and in the gradation filter, when the density filter is less than a predetermined opening value, density (transmission of light) continuously decreases to the side of an opening diameter. By this gradation filter, it is possible to prevent occurrence of crack (flare phenomenon) in the image by means of a blade edge facing the opening part of an imaging light.

As disclosed in, for example, Patent Document 1, the density filter has a thin film rich in light absorption property on a transparent or semi-transparent substrate, and the thin film has an isoconcentration range having equal thickness and uniform transmittance, and a gradation range of the film thickness linearly decreases. Further, Patent Document 2 (Japanese Patent Laid Open No. 2006-78564) discloses lamination of several sheets of metal films rich in light absorption property and dielectric substance films, so that the metal films attenuate light and the dielectric substance films adjust the amount of transmittance in order to prevent reflection at the same time.

The metal film layer is formed with niobium, chromel or titanium, while the dielectric substance layer is formed with oxides of silicon or aluminum, nitride or fluoride. The film layer is coated on an uppermost layer with a layer having hard property such as magnesium fluoride and good water repellant property. These film layers are composed to linearly decrease the film thickness in the gradation range. Such film structures attenuate light to adjust transmitted light quantity, but if density gradient of the dielectric film is large, there is a problem in that a reflection preventing effect cannot be enough obtained.

Patent Document 3 (Japanese Patent Laid Open No. 2004-205777) has proposed a film structure of uniformly forming the film thickness of the dielectric substance layer preventing light reflection in the gradation range. Patent Document 4 (Japanese Patent Laid Open No. 2005-326687) also proposes a film structure of making an inclination gradient of the dielectric substance layer with respect to the inclination gradient of the thickness of the metal film.

Further, for the film forming method in the gradation range layer, a vacuum evaporation equipment has been broadly employed. For example, Patent Document 5 (Japanese Patent Laid Open No. 2005-345746) discloses formation of the gradation range layer with an evaporation film.

Patent Document 5 proposes a film forming method of attaching a substrate on the vacuum evaporation equipment and heating to vaporize evaporation components as rotating an evaporation stage. A mask plate having a mask opening is furnished between an evaporation source and the substrate, and the isoconcentration range is formed on the substrate opposite to the mask opening, and the gradation range is formed around the isoconcentration range.

Patent Document 5 shows, in FIGS. 1A and 1B, a generating mechanism of the gradation range layer by means of the vacuum evaporation equipment. The method radially attaches many of the substrates 50 to the evaporation stage 51 as shown in FIG. 1A. The mask 53 having film coating openings 52 is arranged at a position spaced away from the stage. The stage 51 and the mask 53 are furnished to rotate around a center of the same axis X in the equipment. At a position Y, offset by a determined amount from the rotation axis X, an evaporation source 54 is placed. Under this condition, the stage 51 is rotated to evaporate the film coating components from the evaporation source 54. Then, apart of the film coating components evaporated from the evaporation source 54 is attached onto the substrate from the mask openings 52 and the other is interrupted by the mask 53.

With this structure, when rotating the stage 51 and the mask 53, a geographical relation is constituted as shown in FIG. 2A between the stage 51 and the evaporation source 54. Briefly, if expressing the evaporation source 54 as a point-evaporation source to the substrate 50 attached to the stage 51, the evaporation source 54 rotates as shown in FIG. 2A in an arc locus tilting at a determined angle θ. The tilting angle θ agrees with an angle θ of the substrate 50 attached to the dome shaped stage 51. Then, the evaporation component is projected from the evaporation source 54 through the openings of the mask 53 to the substrate 50 in the arc locus tilting at the angle θ. Therefore, on the substrate, the film layer is formed as shown in FIG. 2B with the thickness d decreasing from d1 to d2. By this film layer, with respect to the transmitted light quantity, transmission is large in the high density part (d1) and it is small in the low density part (d2). That is, in case of generating the prior gradation range layer, the mask plate is provided between the substrate and a target within the evaporation chamber, the film coating component is evaporated to the mask openings from a position tilting at a predetermined angle α. Accordingly, although not disclosed in Patent Document 5, the distance L1 between the target and the mask plate is created to be larger than the distance d between the mask plate and the substrate in order to control such that the evaporation component projected from the target draws linear lines as parallel lights. Thereby, as shown in FIG. 2B, the geographically formed film thickness changes linearly.

As mentioned above, the prior art has adopted the method of film coating by the evaporation equipment as Patent Document 1. But, the above-mentioned method has a disadvantage in that, when producing plural sheets of filter blank materials at the same time, a film thickness is different per each of individual blank materials so that yields are extremely inferior. When mass-producing filters of predetermined transmittance, individual density characteristics are different, and distributions occur in the optical characteristics.

With respect to non-uniformity of the film thickness, when expressing an ideal film thickness with a dotted line in FIG. 5B, the filter formed by the method of Patent Document 2 has a defect of generating distributions in the optical characteristic as shown with a chain line in the same. In the film coating method of the gradation filter by the prior evaporation equipment, the involved problems have been known that when producing plural substrates at the same time, a large distribution occurs in each of the optical characteristics, and the layers in the gradation range do not linearly attenuate. Therefore, for their productions, experience of high level and know-how are required such as managements of the vacuum condition within the chamber, of evaporation condition, or of flying condition within the same.

A reason why distributions of the optical characteristics occur in per blank material in the film coating method disclosed in the above mentioned Patent Document 5 is considered to be in the following. At first, the substrate 50 shown in FIGS. 1A and 1B are attached on the doom shaped stage 51 under the condition of respectively different angles θ. The mask plate 53 is arranged to the substrate 50 at the same angle θ. With respect to the stage attaching the substrate 50 and the mask plates 53, the evaporation source 54 is arranged at the position offsetting at the determined angle α from the rotation center.

Accordingly, the evaporation components flying from the evaporation source 54 pass the mask plate 53 at the respectively different angles θ and carry out the film coating on the substrate. Therefore, the film layers of different widths are formed on the substrate 50a, the substrate 50b and the substrate 50c. On the stage 51 rotating around the center of the rotation axis X, the evaporation components are different in the distances L1, L2 and L3 with respect to the substrate 50a, the substrate 50b and the substrate 50c. Thus, the thicknesses of the films coated on both substrates are naturally different, and this is analyzed as the cause for generating distributions of the optical characteristic.

A reason why the film layers do not attenuate linearly in the film coating method disclosed in Patent Document 5 is considered to be in the following. The film coating method of the same forms, as shown in FIG. 1, the gradation range layer before and after the rotating direction of the substrate 50 and the mask plate 53. Therefore, the evaporation components ejected from the evaporation source 54 are adhered to the gradation range layer as rotating on the substrate 50. Depending on such film coating, the atmosphere within the chamber is changed by rotation of the substrate 50. This change makes the thicknesses of the coated film unstable, and the film thickness as geometrically formed cannot be obtained. Further, in the film coating method of Patent Document 5 of heating to evaporate the evaporation materials within the evaporation chamber, particles of the film coating materials are large, and since the particles of the film coating materials are large, if the film coating conditions are changed even slightly, the thicknesses are largely different, and this is analyzed as the cause for being largely different thicknesses. Concurrently, comparing to use of silicon dioxide as, e.g., the evaporation components, the components evaporating from the evaporation source 54 are generated under unstable conditions as “SiO₂”, “SiO” or their intermediate oxide. Since such oxide shift occurs at random by the film coating means, this is considered to be a cause of not forming a stable film layer.

It is therefore an object of the present invention to provide a film coating method enabling to coat films on a plurality of substrates having the film thickness stable in the gradation range layer decreasing and without distribution.

Further, it is another object of the present invention to provide a film coating method and a film coating equipment of density filters enabling to linearly decrease the film thickness in the gradation range layer without deterioration as time-passing, and to provide density filters using the method and equipment.

Further, objects and advantages of the invention will be apparent from the following description of the invention.

### SUMMARY OF THE INVENTION

To accomplish the above objects, the present invention adopts the following constitution.

At the outset, the density filter is composed of a substrate, dielectric substance layers and metal film layers formed in lamination on the substrate. The dielectric substance layers are coated by sputtering targets of dielectric substances with an introduction gas, followed by applying a reactive gas. The metal film layers are coated by sputtering the targets of metal substances with the introduction gas, and when sputtering the targets, the dielectric substance layers and the metal film layers have gradation range layers with the thicknesses decreasing by diffusion of sputtering particles from the mask opening edge of mask plate forming film coating gap in relation with the substrate.

Further, in the film coating method of forming of the density filter according to an embodiment of the present invention, for forming the dielectric substance layers and the metal film layers in lamination on a substrate by sputtering a plurality of targets composed of at least first and second substances different in the optical characteristic, the dielectric substance layers are coated with sputter particles on the film coating by sputtering the targets with the introduction gas, followed by applying plasma to the film, and the metal film layers are performed with sputtering to the targets of metal substances with the introduction gas and coated, on the substrate, with films with the sputter particles or compounds of the sputter particles and the reactive gas. The dielectric substance film layers and the metal film layers are coated by (1) attaching the substrate onto a cylindrical rotation drum disposed within the film coating chamber, (2) placing the targets substantially in parallel to the surfaces of the substrates with plate materials, (3) arranging the mask plate having mask openings on the rotation drum such that predetermined film coating gaps are formed in relation with the substrates, (4) supplying the sputter voltage to the targets as rotating the rotation drum, and the substrates are formed with the gradation range layer of the film thickness decreasing by diffusing sputtering particles from the mask opening edges of the mask plate at the upper and lower ends of the substrates crossing with the rotating direction of the rotation drum.

The production equipment of the density filter of the invention, for forming, has a film coating chamber, a cylindrical rotation drum disposed within the film coating chamber, a plurality of substrates attached to the rotation drum, a first target of the dielectric substance disposed with a distance from the substrate in a first area sectioned within the film coating chamber, a supply source of plasma (the reactive gas ) disposed in a second area within the film coating chamber, a second target of the metal substance disposed in a third area within the film coating chamber, and a supply source of the reactive gas for sputtering disposed in the first and third areas. The first and second targets are disposed in the film coating chamber substantially in parallel to the surfaces of the substrates with plate materials, the rotation drum is arranged with the mask plates having mask openings such that predetermined film coating gaps are formed in relation with the substrates, and the films are coated by supplying the sputter voltage to the targets as rotating the rotation drum and formed with the gradation range layers of the film thickness decreasing by diffusing sputtering particles occurring in the film coating gaps.

### BRIEF DESCRIPTION OF THE DRAWINGS

FIG. 1A is a model view of a conventional film coating method of a density filter, explaining the equipment structure;

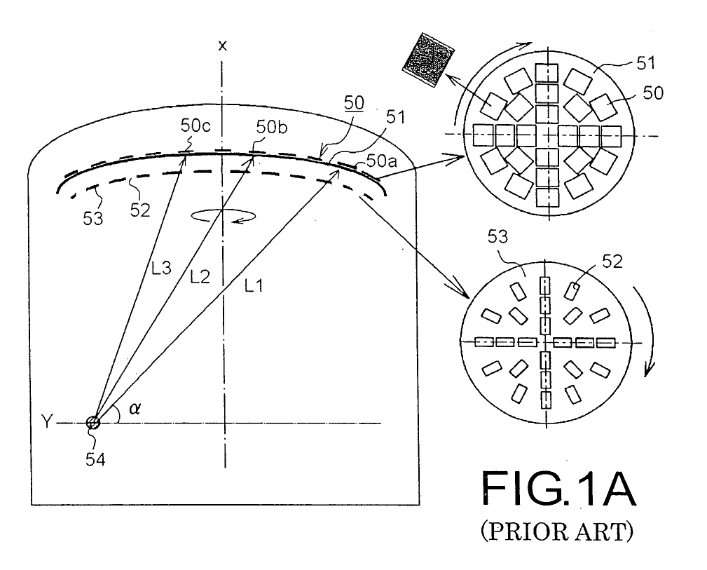

FIG. 1B is the explanatory view of the arranged structure of the substrate and the mask plate of the equipment structure of FIG. 1;

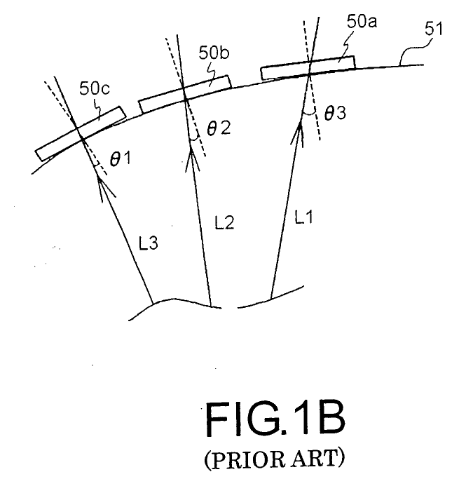

FIG. 2A is the model view of the conventional film coating method of the density filter shown in FIG. 1A, explaining view of an enlarged film coating model of a gradation range layer;

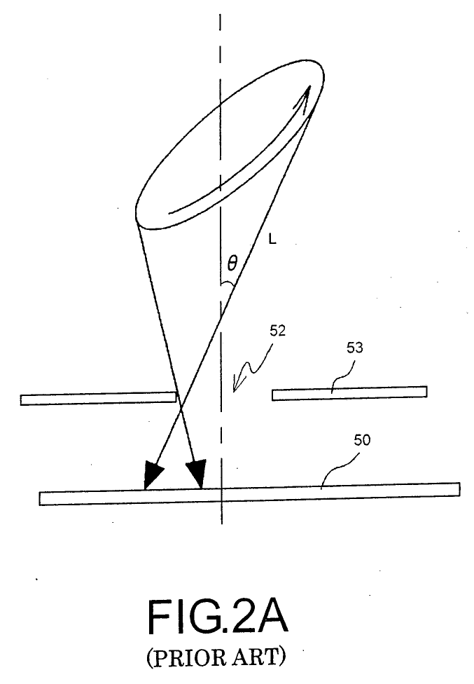

FIG. 2B is the same model view, explaining by enlarging the condition of the film coating on the plate;

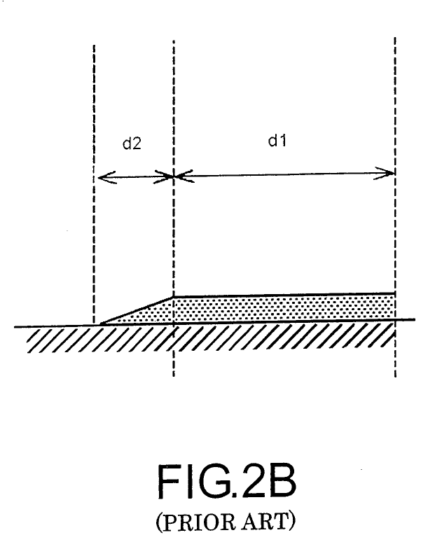

FIG. 3A is a conceptual view of the film coating method according to an embodiment of the present invention, explaining the model causing the evaporation components to fly from the target, viewing from the upper part of the equipment;

FIG. 3B is the same conceptual view, explaining the model causing the evaporation components to fly from the target, viewing from the side part of the equipment;

FIG. 4A shows an arrangement relationship of the substrate and the target, viewing the rotation drum from the oblique upper part;

FIG. 4B shows the arrangement relationship of the substrate and the target viewing from the side of the same;

FIG. 5A is the film coating method of the density filter of an embodiment of the present invention, explaining the film coating of a first layer;

FIG. 5B is the explanatory view of the film coating of a second layer;

FIG. 5C is the explanatory view of the film coating of a third layer;

FIG. 5D is the explanatory view of the film coating of a fourth layer;

FIG. 5E is the explanatory view of generating the films on the coating layer;

FIG. 5F is a cross sectional view of the film layer of the density filter;

FIG. 5G is an enlarged cross sectional view of the layers of the gradation range;

FIG. 5H is the cross sectional view of the film layers of the density filter according to another embodiment of this invention;

FIG. 6A is a schematic view showing the relationship between the film thickness of the density filter according to the embodiment of the present invention and the diffusion distance;

FIG. 6B is the relationship between the density of the density filter and the film coating position;

FIG. 7 is a top view of the sputtering equipment;

FIG. 8 is perspective views showing the light quantity-adjusting device;

FIG. 9A is a characteristic view for explaining AR coat characteristic by the conventional density filter; and

FIG. 9B is a characteristic view for explaining AR coat characteristic according to the embodiments of the present invention.

### DETAILED DESCRIPTION OF PREFERRED EMBODIMENTS

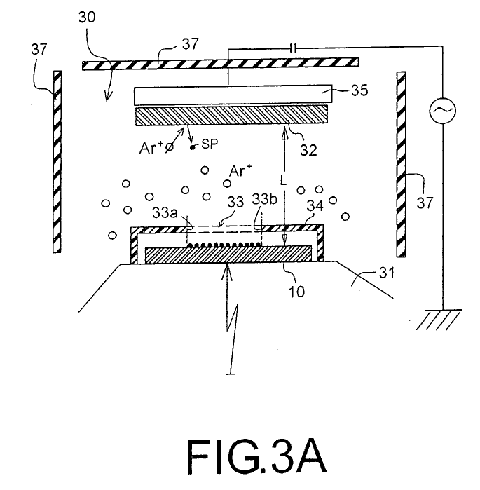

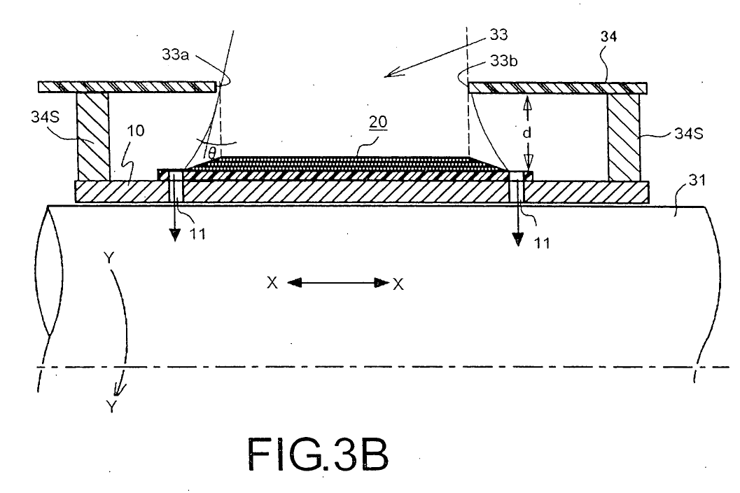

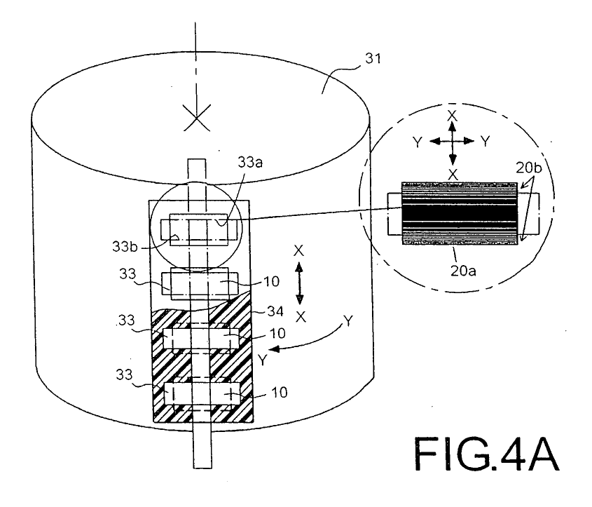

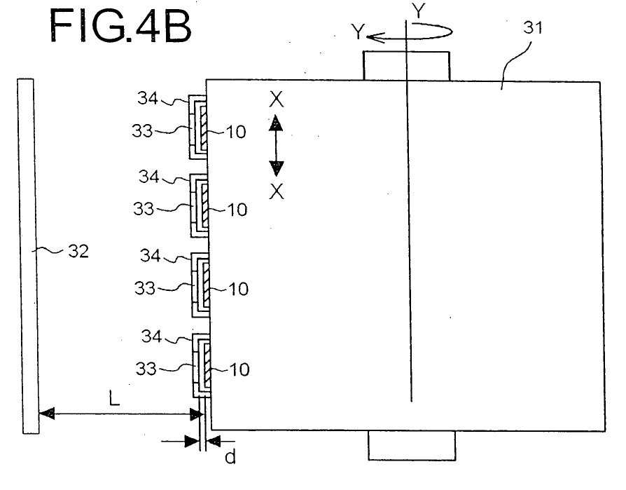

The invention will be explained based on preferred embodiments shown in the drawings. FIGS. 3A and 3B show schematic views of causing the evaporation components to fly from the target, and FIGS. 4A and 4B show the arranging relation of the substrate and the target attached to the rotation drum, and those are the model views showing the conceptual constitution concerned with the embodiments of the present invention.

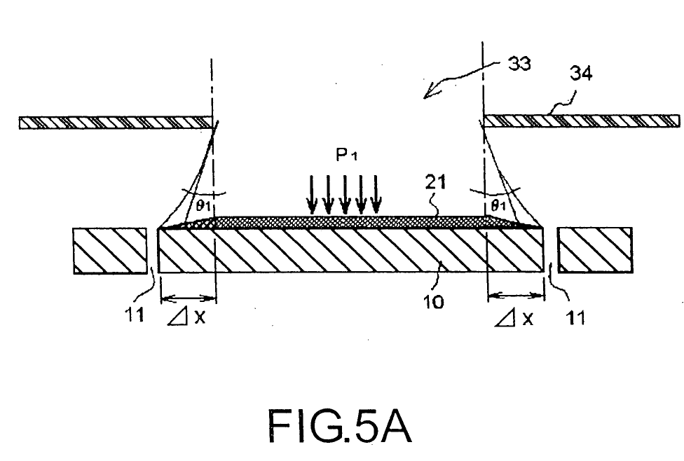

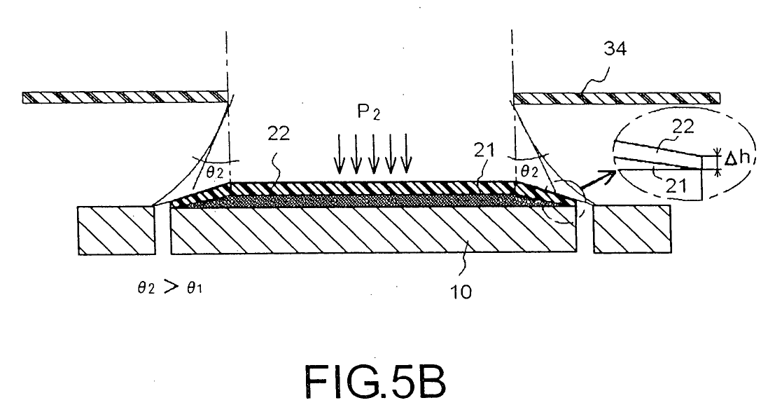

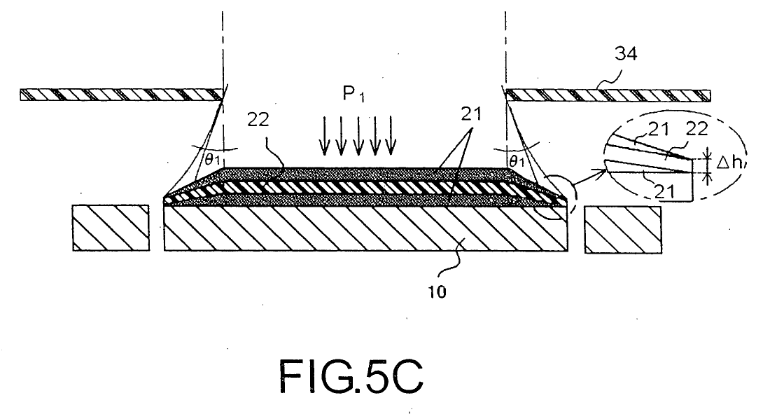

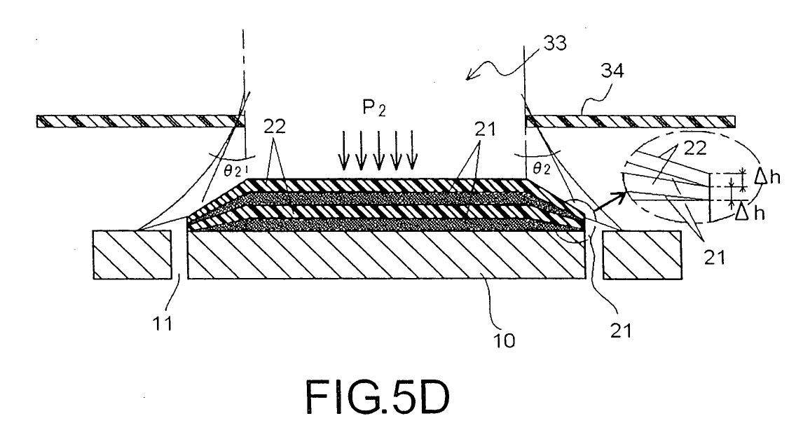

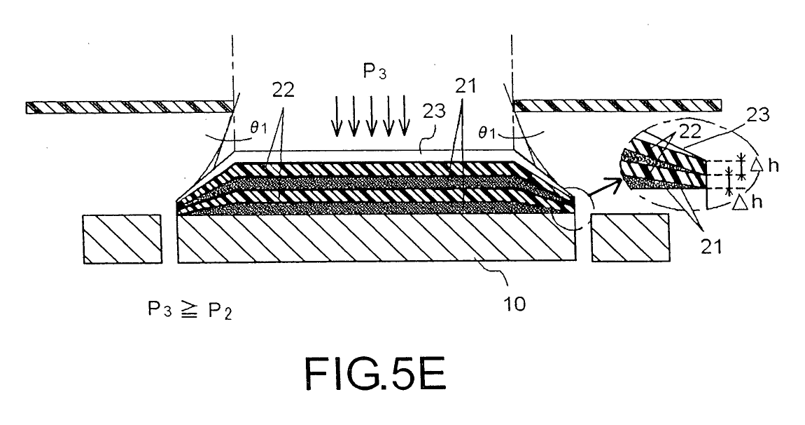

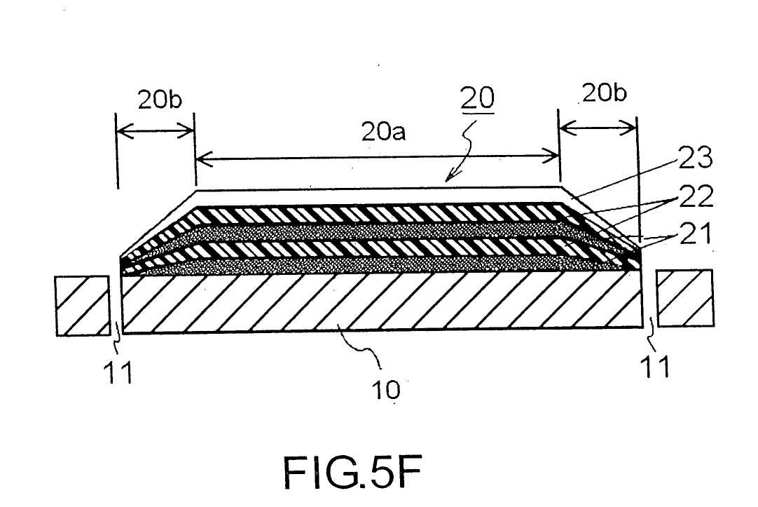

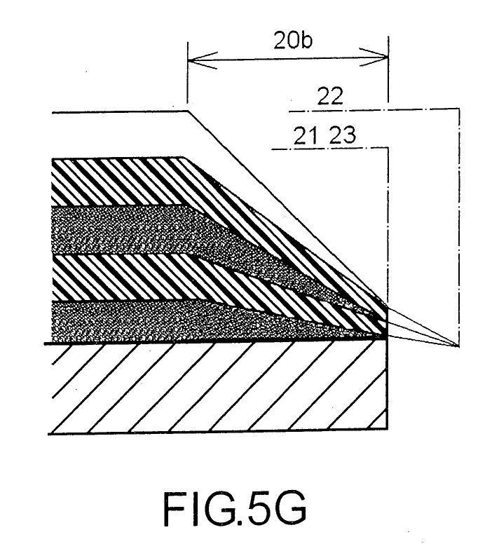

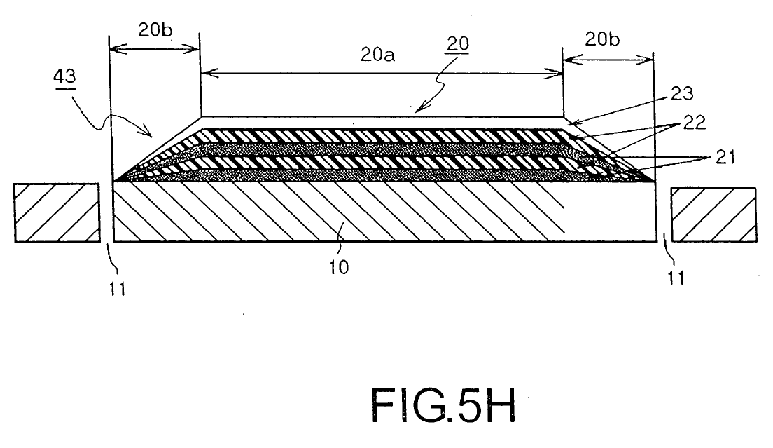

The film coating method of the density filter will be explained. With respect to the light reducing filter or density filter 43, as shown in FIGS. 5F and 5H, the light reducing layer or density film 20 of light absorption property is formed on the substrate or substrate 10. The density film 20 is formed in an isoconcentration or equal concentration range 20a having uniform thicknesses and uniform transmittance and a gradation range 20b of decreasing film thicknesses. The density filter 43 is structured in lamination with the metal film layers 21 rich in light absorption and the dielectric substance layers 22 restraining transmitted light quantity and reflection. The metal film layers 21 and the dielectric substance layers 22 are formed in plural steps of lamination, and the shown density filter 43 is laminated in order, with the substrate, metal film layer, dielectric substance layer, and an uppermost layer is formed with an AR coating layer (Anti Reflection Coating) 23. These film coating substances will be mentioned later.

The film coating performed on the above formed density filter 43 is as follows.

The metal film layer 21 and the dielectric substance layer 22 are formed with a reactive sputtering. As shown in FIG. 3A, the substrate 10 is attached to the stage 31 in the chamber 30. Further, opposite to the substrate 10, the target 32 is positioned. The evaporation stage 31 is structured with a cylindrical rotation drum such that it rotates relatively to the target 32. The target 32 is disposed to a cathode electrode, and a sputter voltage is supplied between the stage 31 and the target 32. The sputter voltage is supplied from, for example, a high frequency power source, and the introduction gas is introduced into the chamber 30 under vacuum. Further, the introduction gas, inside the chamber 30, is under a plasma condition, and electron or ion moves at a high speed and collides with the target 32. Therefore, sputter particles SP fly from the target and attach to the substrate 10.

Further, the metal film layer 21 is structured with the target of the metal substance rich in light absorption property (first target), and the dielectric substance layer 22 is structured with the target (second target) of the dielectric substance (Si or Al), and the first and second targets 21, 22 are different in film coating pressure P of the sputtering introduction gas (Ar or Ne gas), otherwise different in electric energy of the sputter source to be supplied to the target. Adjustment of the sputtering condition will be mentioned later. Under the above mentioned condition, the dielectric substance layer 22 sputters the dielectric substances by the introduction gas in order to coat the film of the sputter particles SP on the substrate, and then the reactive gas is applied to this film to generate a compound and form a film by the generated compound. Briefly, on the substrate 10, the film is coated with particles of silicon or Al alloy, and subsequently, the reactive gas of an oxygen gas, nitrogen gas or fluorine gas are applied. Therefore, an oxide film, nitride film or fluoride film is generated.

The substrate 10 is attached to the evaporation stage 31 (also referred to as rotation drum) within the chamber 30, and when attaching the target 32 to the cathode electrode, the target 32 is positioned in a surface evaporation source with a plate material, and the plate material is disposed substantially parallel to the surface of the substrate 10. As shown in FIG. 3A, the substrate 10 attached on the periphery of the evaporation stage 31 is arranged in parallel to the target 32 with a distance L (flying distance) from this substrate. Thereby, the surface evaporation source and the substrate 10 can keep an equal distance relation in the X-X direction as shown in FIG. 3B.

Further, a mask plate 34 having a mask opening 33 between the target 32 and the substrate 10 is provided. The mask plate 34 is attached to the evaporation stage 31 in a set with the substrate 10. Between the mask plate 34 and the substrate 10, a determined film coating gap d is defined as shown in FIG. 3B.

In particular, the substrate 10 and the mask plate 34 are arranged such that at least one of upper and lower end edges 33a and 33b of the mask opening 33 crossing with the rotation direction (Y-Y) of the rotation drum 31, agrees with the Y-Y direction. The upper and lower opening edges 33a and 33b are disposed parallel to each other, and the mask plate 34 is attached to the rotation drum 31 such that the upper and lower edges 33a and 33b agree with the Y-Y direction of the rotation drum 31.

With such structure, the rotation drum 31 rotates at a fixed speed, high frequency voltage is supplied between the substrate 10 and the target 32, and at the same time, the introduction gas is introduced into the chamber 30. Thereby, the film is coated on the substrate 10. The film coating condition is as shown in FIG. 3B, and in the direction Y-Y of the rotation axis of the rotation drum 31 and at the upper edge 33a and the lower edge 33b of the mask opening 33, the gradation ranges 20b is generated by diffusion of the sputter particles SP within the film coating gap d. Further, the film layer 20a of the isoconcentration range is generated. To explain the film coating condition, the sputter particles SP are diffused from the peripheries of the mask opening 33 in the outer peripheral direction. The diffusion of the sputter particles SP is fine particles of atoms or molecules, and generation of the same is similar to a diffusion phenomena as light. This diffusion has been investigated to attenuate in a cosine function in regard to the diffusion angle θ.

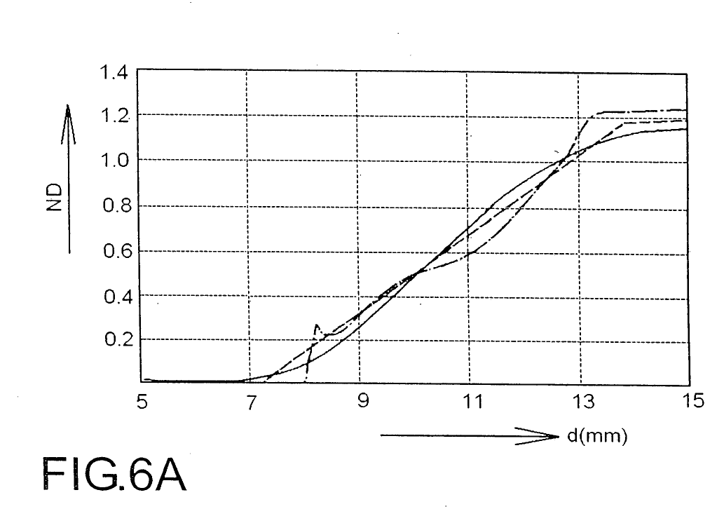

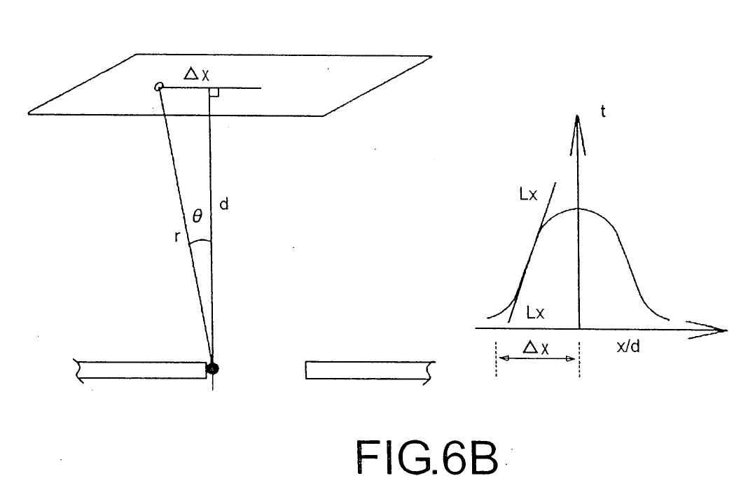

Therefore, the film thickness formed at the outer periphery of the mask opening 33 generated on the substrate 10 is cosine curves as shown in FIG. 6A, and a film thickness is generated along a straight line component shown with Lx in FIG. 6B. Further, the film generation in X-X direction is formed as shown in FIG. 4A crossing with the rotating direction of the substrate 10 rotating with respect to the target 32. It is possible thereby to form the gradation range 20b of the film thickness linearly attenuating without being influenced by rotation of the rotation drum 31.

Further, to explain the structure of the mask plate 34, as shown in FIG. 3B, the substrate 10 is attached to the rotation drum 31 via an attaching jig (not shown). At this time, a frame-shaped spacer member 34S is provided in a space between the substrate 10 and the mask plate 34, and the mask plate 34 is attached to the spacer member 34S. The mask plate 34 is provided with the mask opening 33 corresponding to the film coating area, and at least one of the upper edge 33a and the lower edge 33b is positioned relative to the rotation drum 31 such that a line segment is provided, meeting the rotating direction (Y-Y direction) of the rotation drum 31. Between the substrate 10 and the mask member 34, the film coating d is defined by the spacer member 34S. In this case, the film coating gap d (distance between the substrate and mask plate) is obtained by the following formula with respect to a film coating width Δx as desired (designing value) shown in FIG. 6B [d=k×ΔX/tan θ]. A correcting value k and a diffusion angle θ are found as experimental values from the chamber internal atmosphere.

The above film-coated gradation range layer provides the film thickness almost approximate to an ideal film coating thickness (a dotted line in FIG. 6A) as shown with the solid line in the same. On the other hand, depending on the film coating method by the vacuum evaporation as disclosed in Patent Document 5, the film thickness is shown with the chain line. As apparent from the above description, in the film coating method of the embodiments of the present invention, the film thickness decreases linearly, and the density gradient and light transmittance attenuate linearly.

Concerning the above mentioned film coating method of the embodiments of the present invention, the substrate 10 is composed of a transparent glass or a synthetic resin plate. In case of the synthetic resin, for example, polyethylene terephthalate, polyethylene naphthalate, or norbornane based resins are used. For other qualities of substrate material, suitable ones are selected in response to using circumstances.

The above mentioned dielectric substance layer is composed of oxides of silicon or aluminum, nitride or fluoride. Therefore, for the target 32, the plate member of Si or Al is employed.

For the metal film, the metal oxide rich in light absorption property such as chromel, niobium or titanium is used.

As the coating layer 23, materials rich in hardness or water repellent property as magnesium fluoride is used. In this case, for the target 32, magnesium oxide is used.

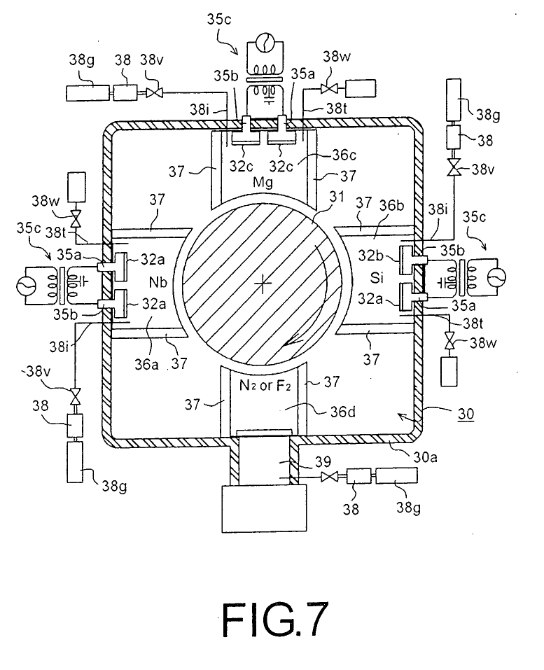

The sputtering equipment as shown in FIG. 7 is composed of an outside housing 30a forming the chamber 30, the cylindrical rotation drum 31 rotatably secured in the chamber 30, and the sputter electrodes 35.

The interior of the chamber 30 is in vacuum, and is sectioned into plural areas 36a to 36d by the shielding plates 37. The interior is sectioned into a first area 36a for sputtering a first target 32a (called as “metal target” hereafter) coating the metal film layer 21, a second area 36b for sputtering a second target 32b (called as “dielectric target”) coating the dielectric substance layer 22, a third area 36c for sputtering a third target 32c (called as “coat layer target”) coating a coating layer 23, and a fourth area 36d for applying an active gas. The first, second and third areas 36a to 36c are respectively stored inside with pairs of sputter electrodes 35a, 35b.

The pairs of sputter electrodes 35a, 35b are connected to AC sources of high frequency, and are arranged so that one side is cathode and the other side is anode. Each of the sputter electrode 35a, 35b is connected to the source coil 35c and is applied with high frequency power of 100 KHz to 40 MHz. The rotation drum 31 having the substrate 10 is applied with bias voltage. Further, each of the sputter electrodes 35a, 35b of the first, second, third areas 36a to 36c is attached with the target 32. The target 32 is composed with a plate shaped material to form a surface evaporation source. The first, second, third areas 36a to 36c are introduced with the introduction gas of argon or neon via controllers 38. Further, 38g is Ar gas supply bombes. The fourth area 36d is supplied with an active gas through the controller 38 from the supply bomb 38g.

In the fourth area 36d, a reactive gas generation chamber 39 is equipped for changing the gas from the supply bomb 38g to plasma and supplying into the fourth area 36d. With this equipment structure, the rotation drum 31 is rotated at a fixed speed for sputtering the metal target 32a of the first area 36a to cause the metal film (e.g. Nb) to adhere onto the substrate 10, and subsequently, sputtering the dielectric target 32b of the second area 36b to cause the dielectric film (e.g. Si) to adhere onto the coating applied to the substrate 10. Then, the dielectric film on the substrate is oxidized to generate the film of oxide (e.g. SiO2).

After laminating plural layers of the metal film layers 21 and the dielectric substance layers 22, the coat layer target 32c of the third area 36c is sputtered to cause AR coat layer 23 to adhere onto the uppermost layer.

When coating the density filter 43, the substrate 10 and the mask plate 34 are attached to the rotation drum 31, and the sputter particles of the film component are caused to fly toward the substrate 10 from the surface evaporation source parallel to the substrate 10. Between the mask plate 34 and the substrate 10, the film coating gap d of the fixed space is formed. Accordingly, the substrate 10 corresponding to the mask opening 33 of the mask plate 34 is formed with the isoconcentration range 20a and the gradation range 20b of the film thickness linearly decreasing at the periphery of the upper end edge 33a and the lower end edge 33b of the mask opening 33.

Thus, when forming the gradation range layer 20b at the upper and lower edges 33a and 33b, respectively, of the mask opening crossing with the rotating direction of the rotating substrate 10, in the embodiments of the present invention, “adjusting the applied voltage of the sputter source” or “adjusting the film coating pressure of the introduction gas” or “adjusting the mass of the introduction gas” is made in forming the metal film layer 21 and the dielectric substance layer 22. In the following paragraphs, the above structures will be explained.

The source coil 35c is connected to the sputter electrodes 35a, 35b, and AC power 35f is supplied to the source coil 35c (see FIG. 7). Then, voltages to be supplied to the first area 36a and the second area 36b are varied. The fluctuation of voltage is adjusted by varying bias voltage to be impressed to the rotation drum 31.

The rotation drum 31 furnished with the substrate 10 and kinetic energy of the sputter particles from the first, second, third targets 32a, 32b, 32c are different owing to the target and the substrate. The supplied voltage w1 when the metal film layer 21 adheres to the substrate 10 by sputtering the first target 32a and the supplied voltage w2 when the dielectric substance layer 22 adheres to the substrate 10 by sputtering the second target 32b are changed such that the latter is larger (w1<w2). The voltage w3 when adhering to the surface coating layer 23 is determined to be larger as (w1<w3).

The first area 36a, second area 36b and third area 36c are supplied with the introduction gas from the bomb 38g. The gas pressure within these areas is adjusted by controlling an adjusting valve 38v of an introduction opening 38i and an adjusting valve 38v of a discharge opening 38t. It is possible thereby to adjust the film coating pressure of the active gas in the areas by adjusting the adjusting valves 38v, 38w. The film coating pressures of the active gases in the first area 36a sputtering the first target (metal substance) 32a and in the second area 36b sputtering the second target (dielectric substance) 32b are varied. The film coating pressure P2 of the second area is set to be larger than the film coating pressure P1 of the first area (P1<P2). Then, the sputter particles flying from the respective targets reach the mask plate 34 as colliding with rough introduction gas ion, otherwise, reach the mask plate 34 as colliding with dense gas ion. With respect to the diffusion amount of the sputter particles diffusing from the mask plate within the film coating gap d, the former is small (less) and the latter is large (high).

In the embodiments of the present invention, the coating of the metal film layer 21 and the dielectric film layer 22 is as follows. Referring to FIGS. 5A to 5C and 5D to 5G, explanation will be made as to the case of changing the film coating pressure. As shown in FIG. 5A, when coating the first metal film layer 21 on the substrate 10, the film coating pressure of the introduction gas is set to the determined pressure P1. The film coating gap d is fixed such that the film width Δx in the gradation range layer is zero.

Further, in coating the dielectric substance layer 22 on the first metal film layer 21 as shown in FIG. 5B, when sputtering the target 32b, the film coating pressure P2 of the introduction gas supplied to the second area 36b is set to be at a larger value than P1. Then, the dielectric film 22 is formed to be of a moderate density gradient having the film thickness of shown Δh at the film end edge. This is because the diffusion angle θ2 (θ2>θ1) of the sputter particle diffusing from the end edge 33a of the mask opening 33 is larger than the angle θ1.

When coating the first metal film layer 21 and coating a second metal film layer 22 on the second dielectric substance layer as shown in FIG. 5C, the same film coating conditions (film coating P1 and diffusion angle θ1) as those of the first film coating (FIG. 5A) are set. Thereby, the film of the same linear density gradient as the first film layer is obtained.

When coating the first metal film, the second dielectric film, and the dielectric substance layer on the third metal film, as shown in FIG. 5D, the same conditions as those of the second film coating are set. Thereby, the film of the same moderate density gradient as the second film coating and the film thickness Δh is formed.

After coating plural steps of films, a coating layer 23 is formed on the surface layer. The coating layer 23 is comparatively hard and rich in water repellent property, and is formed not to weaken the interior dielectric substance layer 22 and metal layer 21. In this case, similar to the above dielectric film, the film coating conditions are set as the gradient of the film thickness being as moderate as possible. For example, the film coating pressure P3 is set as P3≧P2.

FIG. 5F shows the film layer structure of the final film coated as mentioned above. The uniform film layers are composed of the dielectric substance layers 22 and the metal film layers 21 of determined thicknesses, and the gradation ranges are formed as the film thicknesses linearly decreases. At this time, with respect to the gradients of the metal film layers 21, the gradients of the dielectric film layers 22 are formed at moderate angles. As shown in FIG. 5G, the thicknesses of the film end edges, i.e., the metal film layers 21 and the dielectric film layers 22 are formed as “zero” and “Δh”, respectively.

Further, in the embodiments of the present invention, the film coating pressure is adjusted by controlling the amount of introducing the introduction gas by the above mentioned controller 38. By adjusting the film coating pressure, as shown in FIG. 5H, it is possible to meet the film widths in the gradation range 20b at the end edges by the dielectric substance layers 22 and the metal film layers 21. In short, since the thickness gradient in the gradation range 20b is determined per film layer by adjusting the pressure of the introduction gas, for example, the thickness gradient of the dielectric substance layer 22 and that of the metal film 21 may be determined respectively and separately.

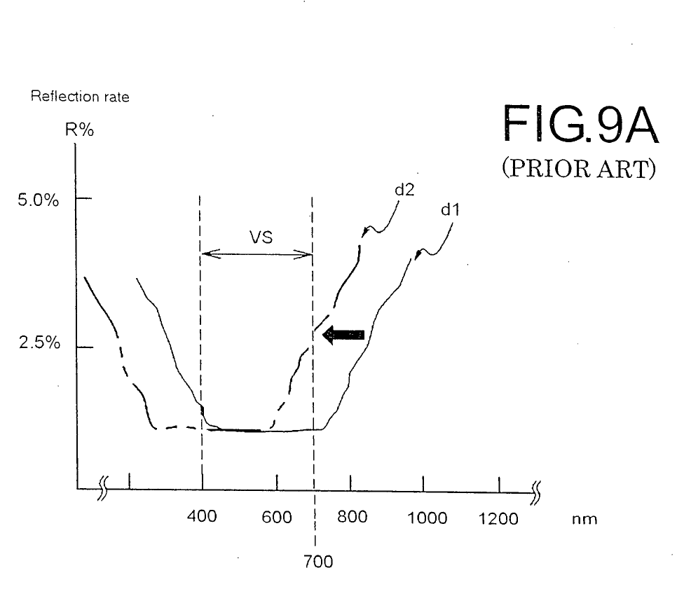

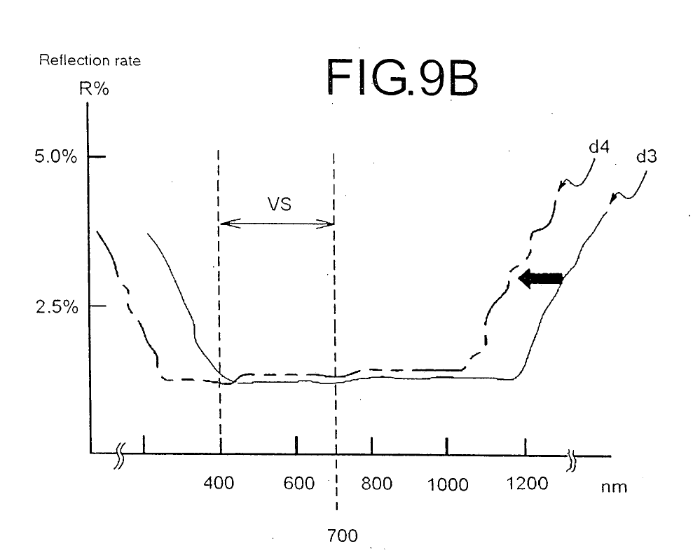

Further, when determining the thickness gradient of the dielectric substance film layer 22 and that of the metal film layer 21, for restraining change of reflectance R % in the gradation range layer and avoiding ghost phenomena, the AR coating treatment is ordinarily carried out as shown in FIG. 9A in the visible light range VS from 400 nm to 700 nm. But since the film thickness becomes thin in the gradation portion as shown in the same, the thickness is easily ready for distribution, and the reflectance characteristic tends to slide to the low wavelength from d1 to d2 owing to changing of the film thickness. Thus, by increasing the thickness gradient of the dielectric substance film layer 22, that of the metal film 21 and the number of layers, for restraining change of reflectance R % of the range of the AR coating treatment of the visible light range VS from 400 nm to 700 nm until the high wavelength of around 1200 nm, the range of the AR coating treatment can be widened as shown in FIG. 9B. Even if the film thickness of the gradation portion changes more or less by this widened range AR coating treatment and the reflectance characteristic slides to the side of the low wavelength as from d3 to d4, the AR coating characteristic in the visible light range VS from 400 nm to 700 nm can be maintained almost constant.

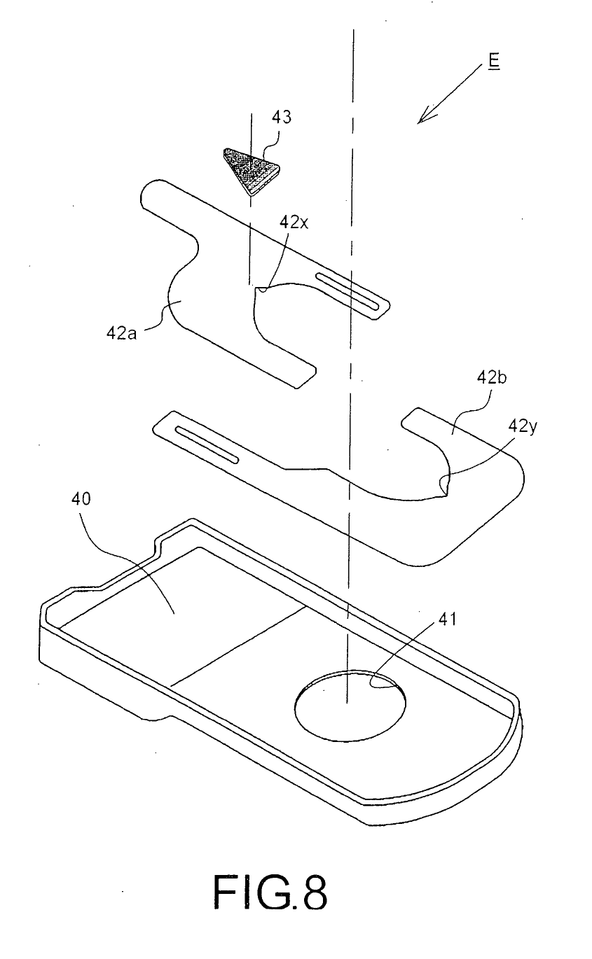

A light quantity adjusting device E arranges, as shown in FIG. 8, the substrate 40 and one sheet or several sheets of light quantity adjusting blades 42 on a light path opening 41 formed in the substrate 40 in manners of the light quantity adjusting blades 42 being opened and closed. The quantity of light passing through the light path opening 41 is adjusted with the light quantity adjusting blades 42. The shown device E is composed to adjust the quantity of light with a pair of blades 42a, 42b and the blades 42a, 42b are formed with bottlenecks 42x, 42y for adjusting the quantity of light under small opening conditions. One of the blades 42a is attached with the density filter 43. The density filter 43 is formed by cutting a mono-density or isoconcentration range 20a and the gradation range layer 20b on the substrate 10, and attached to the light quantity adjusting blades 42a for increasing transmittance as going to the center of light path.

For forming the film by attaching the substrate on the periphery of the cylindrical rotation drum disposed in the film coating chamber, the targets are composed as a plate shape and arranged almost in parallel to the surface of the substrate, and are subjected to the sputtering via the mask plate defining the determined gap in relation with the substrate for coating the film, and therefore, the embodiments of the resent invention provide the following effects.

The substrate attached to the rotation drum and the mask plate are maintained in the same position with respect to the targets when coating the films by rotation of the rotation drum. Accordingly, since the positional relation of each of the film coating factors is stable, even if the plural substrates are arranged on the rotation drum, substantially uniform film layers are formed, and distributions do not occur in the film layer per substrate.

The dielectric substance film layer is formed on the substrate with the sputter particles by sputtering the targets of the dielectric substance with the introduction gas, and formed with the compound by applying plasma to the formed films, and accordingly, the films are uniform and there is no danger without deterioration occurring as time-passes. In short, in case of silicon or aluminum, these fine particles form the films on the substrates, and the reactive gas such as oxygen, nitrogen or fluorine is applied thereto for forming the compound films. Therefore, the films are not formed with unstable molecular structures. The optical characteristics are not deteriorated by changing the dielectric substance film layer owing to the gases (oxygen or nitrogen in air) under the using circumstances.

Since the gradation range layer of the thickness linearly decreasing is formed with the sputter particles, diffusing from the mask opening having the film coating gaps in relation with the substrate, the particle diffusion gradually attenuates from the opening end edges of the mask opening toward the periphery. Comparing with the evaporation components in the conventional vacuum evaporation method, the sputter particles of the invention are very fine, and when diffusing from the mask opening, the particles attenuate similar to the light diffusion, and the films of uniform thickness are produced on the substrates in the normal direction of the mask opening. Around the opening ends, the films (gradation range layer) gradually attenuate or decrease in proportion to the diffusion angle.

The gradation range layer is formed with sputter particles diffusing to the peripheries of the upper and lower edges of the mask openings crossing with the rotating direction of the mask openings, so that influences by rotation of the rotation drum can be suppressed, and a stable transmittance (without distribution) can be produced.

When sputtering the first and second plural substances with the introduction gas to form the films of the sputter particles on the substrates, gradation range layer of the thickness decreasing by diffusion of the sputter particles generating within the film coating gaps between the substrates and the mask openings is formed. At this time, by adjusting pressure of the introduction gas of sputtering the targets, or by adjusting electric energy of the sputter source of supplying to the targets, the density gradients of the gradation range layers are fluctuated in the first substance and the second substance. Therefore, the embodiments of the present invention display the following effects.

When forming the density filters shaped in layer with the metal films rich in light absorption property and with the dielectric substance film, for example, it is possible to form the metal film in the density gradient changing linearly light absorption characteristic, and generate the dielectric substance film layer in the moderate density gradient not spoiling reflection preventing effect. In particular, the density gradient can be easily generated by allowing the film coating pressure of the introduction gas to be introduced into the chamber, otherwise, controlling the supplied electric energy of voltage or frequency to be supplied to the targets.

By adjusting the shapes of the mask plates or the positions to the substrates by the conventional vacuum evaporation equipment for forming the density gradient, the position of the mask slides or distributions occur in the plural substrates. Comparing with the conventional equipment, the invention can easily adjust the film thickness by controlling the very simple evaporation condition.

By adjusting the film coating pressure or supply voltage or the mass of the introduction gas, the density gradient is fixed, and therefore even if the dimension of the film substrate or the film coating substances are different in the same sputtering device, the film thickness of the gradation range layer can be easily adjusted to be optimum.

When composing the density film with the metal films rich in light absorption characteristic and the dielectric substance film layer of preventing the transmitted light quantity and light reflection, if forming the metal film in the linear density gradient and forming the density filter in the moderate density gradient unable to prevent the anti-reflection, it is possible to provide the density filters excellent in light density characteristic and reflection preventing characteristic at cheap cost.

By forming the gradation range layer in lamination with the dielectric substance film layer and the metal layer, forming the AR coating layer of magnesium fluoride or other hard film on the uppermost surface, and deciding the dielectric substance film layer forming the gradation range layer in response to the zone width of the AR coating layer and the thickness gradient of each of the metal layers and the number of the layers, the invention displays the following effects.

By adjusting the thickness gradient of the dielectric substance film layer and that of the metal film, increasing the number of the layers, and restraining the range of the AR coating treatment of the visible light range from 400 nm to 700 nm until the high wavelength of around 1200 nm, the range of the AR coating treatment can be widened, and even if the film thickness of the gradation portion changes more or less and the reflectance characteristic slides to the side of the low wavelength, the AR coating characteristic in the visible light range VS from 400 nm to 700 nm can be maintained almost constant.

The disclosures of Japanese Patent Applications No. 2007-166249 filed on Jun. 25, 2007, No. 2007-166250 filed on Jun. 25, 2007 and No. 2007-171780 filed on Jun. 29, 2007 are incorporated as a reference.

While the invention has been explained with reference to the specific embodiments of the invention, the explanation is illustrative and the invention is limited by the appended claims.

What is claimed is:

1. A density filter comprising:
a substrate, and
a plurality of sputtered dielectric substance layers and a plurality of sputtered metal film layers alternately laminated on the substrate,
wherein the dielectric substance layers and the metal film layers have gradation range layers with a decreasing thickness at an edge thereof, sputtering particles gradually decreasing in each of the gradation range layers.

2. The density filter as set forth in claim 1, wherein the gradation range layers comprise the dielectric substance layers and the metal layers laminated together, and a magnesium fluoride or anti reflective coating layer of hard film formed thereon.

3. The density filter as set forth in claim 2, wherein the gradation range layers of the dielectric substance layers and the metal layers have a thickness gradation and a sheet number set in response to a range width of the anti reflective coating layer.

4. The density filter as set forth in claim 1, wherein the gradation range layers are configured such that a density gradient of the dielectric substance layer and that of the metal films are different, when sputtering evaporation targets, owing to difference in film coating pressure of the introduction gas and/or difference in electric energy of the sputtering source applied to the evaporation targets.

5. The density filter as set forth in claim 4, wherein the density gradient of the metal layer is smaller than that of the dielectric substance layer in the gradation range layer.

6. A film coating method of a density filter, comprising:
sputtering on a target of a substance by a gas to coat a substrate with sputter particles or compounds of the sputter particle and the gas, to form a metal film layer,
coating a dielectric substance layer with sputter particles on the substrate by sputtering a target with gas, followed by applying plasma to coat a film, the sputter particles of the dielectric substance being different from those of the metal film layer in optical characteristic,
laminating a plurality of said dielectric substance layers and a plurality of said metal film layers alternately on the substrate by sputtering,
wherein the dielectric substance layers and the metal film layers are formed to have gradation range layers at edges thereof, said gradation range layer having thickness gradually decreasing by diffusing spattering particles.

7. The film coating method of density filter as set forth in claim 6, wherein the dielectric substance film layers and the metal film layers are coated by:
attaching the substrate onto a cylindrical rotation drum disposed within a film coating chamber;
placing the targets parallel to a surface of the substrate;
arranging a mask plate having a mask opening on the rotation drum such that predetermined film coating gaps are formed in relation with the substrate;
supplying spatter voltage to the targets as rotating the rotation drum so that the substrate is formed with the gradation range layers of the film thickness decreasing by diffusing spattering particles from mask opening edges of the mask plate at upper and lower ends of the substrate crossing with a rotating direction of the rotation drum.

8. The film coating method of density filter as set forth in claim 7, wherein the film coating gap between the substrate and the mask plate is defined with a determined distance set in response to a film coating width of the gradation range layer.

9. The film coating method of density filter as set forth in claim 7, wherein the film coating gap between the substrate and the mask plate is defined with a determined distance to a distance between the target and the substrate.

10. The film coating method of density filter as set forth in claim 7, wherein
the substrate and the mask plate are disposed on a periphery of the rotation drum,
the film coating gap is defined with a spacer member arranged between the substrate and the mask plate, and
at least one of the upper and lower ends of the mask opening formed in the mask plate is arranged on a straight line with the rotating direction of the rotation drum.

11. The film coating method of density filter as set forth in claim 7, wherein a pressure of the gas forming the dielectric substance layer and a pressure of the gas forming the metal film layer are determined such that film ends of the gradation range layers correspond to each other.

12. The film coating method of density filter as set forth in claim 7, wherein
the substrate is a transparent plastic or a transparent glass,
the substrate is provided with a cutout opening in end edges forming the gradation range layer of a film coating area, and
the cutout opening has a passage for adjusting dispersion of the spatter particles.

13. The film coating method of density filter as set forth in claim 7, wherein the gradation range layers are configured such that density gradient of the first substance and that of the second substance are different, when sputtering the evaporation targets, owing to difference in film coating pressure of the gas and/or difference in electric energy of the sputtering source applying to evaporation targets.

14. The film coating method of density filter as set forth in claim 13, wherein the first substance generates the metal film rich in light absorption property, the second substance generates the dielectric substance layer, and the density gradient of the dielectric substance layer is set to be smaller than that of the gradation range layer.

15. An apparatus for forming a density filter of dielectric substance layers and metal film layers on a substrate, comprising:
a film coating chamber;
a cylindrical rotation drum disposed within the film coating chamber;
a plurality of substrates attached to the rotation drum;
a first target of a dielectric substance disposed with a distance from the substrate in a first area sectioned within the film coating chamber;
a supply source of a reactive gas disposed in a second area within the film coating chamber;
a second target of a metal substance disposed in a third area within the film coating chamber;
a supply source of the reactive gas for spattering disposed in the first and third areas,
wherein the first and second targets are disposed in the film coating chamber substantially parallel to the surfaces; and
the rotation drum is arranged with the mask plates having mask openings such that predetermined film coating gaps are formed in relation with the substrates so that the film layers are coated by supplying sputter voltage to the targets as rotating the rotation drum, and formed with gradation range layers of film thickness decreasing by diffusing sputtering particles occurring in the film coating gaps.

16. The apparatus for forming density filter as set forth in claim 15, wherein the mask plate is arranged such that upper and lower end edges of the mask opening agree with a rotating direction of the rotation drum, and the substrate is formed with the gradation range layers in the upper and lower end edges following a rotating direction of the rotation drum.

17. The apparatus for forming density filter as set forth in claim 15, wherein a pressure of a gas forming the dielectric substance layer and that of the gas forming the metal film layer are determined such that film ends of the gradation range layers correspond together.
